(19) United States
(12) Patent Application Publication
(10) Pub. No.: US 2025/0221180 A1
(43) Pub. Date: Jul. 3, 2025

(54) Display Device

(71) Applicant: LG Display Co., Ltd., Seou (KR)

(72) Inventors: Yan Jin, Gimpo-si (CN); Yoojin Kang, Seoul (KR)

(21) Appl. No.: 18/816,995

(22) Filed: Aug. 27, 2024

(30) Foreign Application Priority Data
Dec. 27, 2023 (KR) 10-2023-0193275

(51) Int. Cl. H10K 59/123; H10K 59/131; H10K 59/80; H10K 102/00

(52) U.S. Cl. CPC H10K 59/123; H10K 59/131; H10K 59/80524; H10K 59/878; H10K 2102/3031

(57) ABSTRACT

A display device includes a substrate, a plurality of pixels on the substrate and are configured to operate in an emission mode or a transparent mode. Each of the plurality of pixels includes a first emission area, a second emission area that encloses the first emission area, and a transmission area that is adjacent to the second emission area. During the emission mode, the first emission area and the second emission area emit light, and during the transparent mode, the first emission area emits light and the second emission area and the transmission area function as a transparent area. Accordingly, a size ratio of the transmission area and the emission area may be controlled according to the usage environment of the display device.

### CROSS-REFERENCE TO RELATED APPLICATION

This application claims the priority of Republic of Korea Patent Application No. 10-2023-0193275 filed on Dec. 27, 2023, which is hereby incorporated by reference in its entirety.

### BACKGROUND

### Field

The present disclosure relates to a display device, and more particularly, to a display device which controls a size ratio of a transmission area and an emission area according to a usage environment of a display device.

### Description of the Related Art

As display devices which are used for a monitor of a computer, a television, or a cellular phone, there are an organic light emitting display (OLED) device, which is a self-emitting device, a liquid crystal display (LCD) device, which requires a separate light source, and the like.

An applicable range of the display device is diversified to personal digital assistants as well as monitors of computers and televisions and a display device with a large display area and a reduced volume and weight is being studied.

Recently, studies on a transparent display device are being actively conducted. The transparent display device refers to a display device which allows a user to recognize not only visual information implemented on a display panel from a front surface of the panel, but also objects, etc. located on a rear surface of the display panel. To this end, the transparent display device includes an emission area in which driving elements are disposed to implement an input image and a transmission area through which external light is transmitted. In the transparent display device, it is necessary to sufficiently ensure an area occupied by the transmission area to allow the user to more clearly and visibly recognize background information located on the rear surface of the display panel. It is further necessary to sufficiently ensure an area occupied by the emission area to ensure a required aperture ratio.

### SUMMARY

An object to be achieved by the present disclosure is to provide a display device which controls a size ratio of a transmission area and an emission area according to a usage environment of a display device.

Objects of the present disclosure are not limited to the above-mentioned objects, and other objects, which are not mentioned above, can be clearly understood by those skilled in the art from the following descriptions.

In one embodiment, a display device comprises: a substrate; and a plurality of pixels on the substrate, the plurality of pixels configured to operate in an emission mode during which the plurality of pixels emit light or a transparent mode, wherein each of the plurality of pixels includes: a first emission area; a second emission area that encloses the first emission area in a plan view of the display device; and a transmission area that is adjacent to the second emission area, wherein the first emission area and the second emission area emit light during the emission mode, and the first emission area emits light and the second emission area does not emit light during the transparent mode such that the second emission area and the transmission area function as a transparent area during the transparent mode.

In one embodiment, a display device comprises: a substrate; a plurality of pixels on the substrate, each of the plurality of pixels including a first emission area, a second emission area enclosing the first emission area in a plan view of the display device, and a transmission area through which light is transmitted; a plurality of first thin film transistors and a plurality of second thin film transistors on the substrate; an over coating layer that covers the plurality of first thin film transistors and the plurality of second thin film transistors; a second anode electrode on the over coating layer, the second anode electrode electrically connected to a second thin film transistor from the plurality of second thin film transistors; a second bank on the second anode electrode and the over coating layer and exposes a part of the second anode electrode, the exposed part of the second anode electrode defining the second emission area; a second emission layer on the exposed part of the second anode electrode; a second cathode electrode on the second emission layer; an insulating layer on the second cathode electrode; a first anode electrode on the insulating layer and overlapping the second anode electrode, the first anode electrode electrically connected to a first thin film transistor from the plurality of first thin film transistors; a first bank on the first anode electrode and the insulating layer and exposes a part of the first anode electrode, the exposed part of the first anode electrode defining the first emission area; a first emission layer on the exposed part of the first anode electrode; and a first cathode electrode on the first emission layer.

In one embodiment, a display device comprises: a substrate; a first thin film transistor and a second thin film transistor on the substrate; a first light emitting element that is connected to the first thin film transistor, the first light emitting element configured to emit light; a second light emitting element that is connected to the second thin film transistor and is overlapped by the first light emitting element, the second light emitting element configured to emit light, wherein the first thin film transistor drives the first light emitting element to emit light and the second thin film transistor drives the second light emitting element to emit light during a first mode of the display device, and the first thin film transistor drives the first light emitting element to emit light and the second light emitting element does not emit light during a second mode of the display device.

Other detailed matters of the exemplary embodiments are included in the detailed description and the drawings.

According to the exemplary embodiment of the present disclosure, the display device may control a size ratio of a transmission area and an emission area according to a usage environment.

According to the exemplary embodiment of the present disclosure, in the display device, in order to implement an input image, in an on-screen mode which is an emission mode in which light is emitted from the entire surface of the display panel, both a first emission area and a second emission area emit light. Accordingly, an emission size is maximized to implement a clear image quality.

According to the exemplary embodiment of the present disclosure, in the display device, in a see-through mode which is a transparent mode in which an object, etc. located on a rear surface of the display panel is recognized, the first emission area emits light and the second emission area functions as a transmission area to maximize a transmission size.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic diagram of a display device according to an exemplary embodiment of the present disclosure;

FIGS. 2A to 2D are plan views for one pixel according to an exemplary embodiment of the present disclosure;

FIG. 3 is a flowchart for setting a plurality of pixels to an emission mode or a transparent mode according to an exemplary embodiment of the present disclosure;

FIG. 4 is an equivalent circuit diagram of a plurality of pixels according to an exemplary embodiment of the present disclosure;

FIG. 5A is a plan view illustrating an emission mode of a display device according to an exemplary embodiment of the present disclosure;

FIG. 5B is a plan view illustrating a transparent mode of a display device according to an exemplary embodiment of the present disclosure;

FIG. 6 is a schematic plan view illustrating an emission area of a plurality of pixels according to an exemplary embodiment of the present disclosure;

FIG. 7 is a cross-sectional view taken along the line VII-VII′ of FIG. 6 according to an exemplary embodiment of the present disclosure;

FIG. 8 is a cross-sectional view taken along the line VIII-VIII′ of FIG. 6 according to an exemplary embodiment of the present disclosure; and

FIG. 9 is a schematic plan view illustrating an emission area of a plurality of pixels according to another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various exemplary embodiments of the present disclosure will be described in detail with reference to the accompanying drawings.

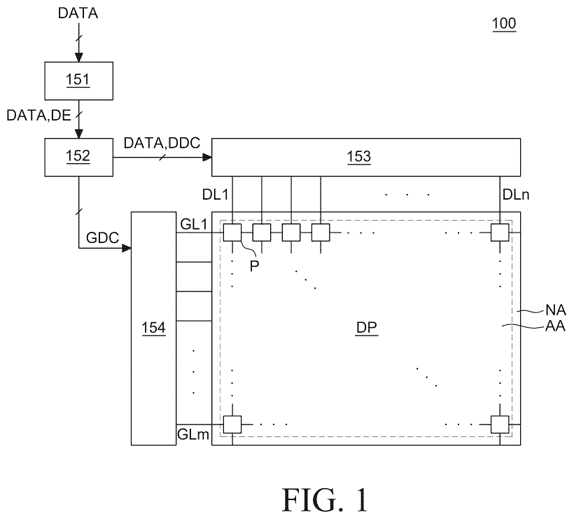

FIG. 1 is a block diagram of a display device according to an exemplary embodiment of the present disclosure.

Referring to FIG. 1, a display device 100 according to an exemplary embodiment of the present disclosure may include an image processor 151, a timing controller 152, a data driver 153, a gate driver 154, and a display panel DP.

At this time, the image processor 151 may output a data signal DATA supplied from the outside, a data enable signal DE, and the like. The image processor 151 may output one or more of a vertical synchronization signal, a horizontal synchronization signal, and a clock signal in addition to the data enable signal DE.

The timing controller 152 is supplied with the data signal DATA together with a driving signal including the data enable signal DE or the vertical synchronization signal, the horizontal synchronization signal, and the clock signal, from the image processor 151. The timing controller 152 may output a gate timing control signal GDC for controlling an operation timing of the gate driver 154 and a data timing control signal DDC for controlling an operation timing of the data driver 153, based on the driving signal.

Further, the data driver 153 samples and latches the data signal DATA supplied from the timing controller 152 in response to the data timing control signal DDC supplied from the timing controller 152 to convert the data signal into a gamma reference voltage and output the converted gamma reference voltage. The data driver 153 may output the data signal DATA through data lines DL1 to DLn.

Further, the gate driver 154 may output the gate signal while shifting a level of the gate voltage, in response to the gate timing control signal GDC supplied from the timing controller 152. The gate driver 154 may output the gate signal through gate lines GL1 to GLm.

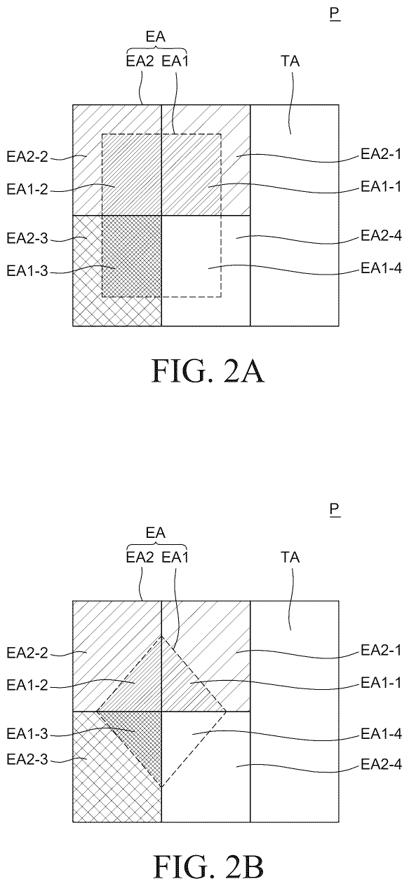

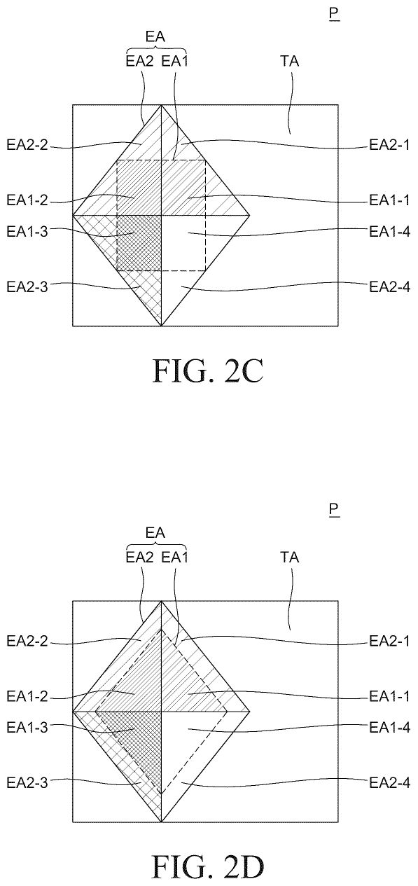

The display panel DP may display images while a pixel P emits light in response to the data signal DATA and the gate signal supplied from the data driver 153 and the gate driver 154. A detailed structure of the pixel P will be described in detail with reference to FIGS. 2 to 5.

The display panel DP may include an active area AA and a non-active area NA.

The active area AA is an area where images are displayed in the display panel DP.

In the active area AA, a plurality of pixels P and a circuit for driving the plurality of pixels may be disposed. The plurality of pixels P may be disposed in a matrix on the substrate 100 of the display panel DP, but is not limited thereto. A pixel P is a minimum unit which configures the active area AA and a display element may be disposed in each of the plurality of pixels P. For example, an organic light emitting diode which includes an anode, an emission layer, and a cathode may be disposed in each of the plurality of pixels P, but it is not limited thereto. Further, a circuit for driving the plurality of pixels P may include a driving element and a wiring line. For example, the circuit may be configured by a thin film transistor, a storage capacitor, a gate line, and a data line, but is not limited thereto.

The non-active area NA is an area where no image is displayed.

The non-active area NA is bent so as not to be seen from a front surface or blocked by a case (not illustrated) and may also be referred to as a bezel area.

Even though in FIG. 1, it is illustrated that the non-active area NA encloses a rectangular active area AA, shapes and placements of the active area AA and the non-active area NA are not limited to the example illustrated in FIG. 1. That is, the active area AA and the non-active area NA may have shapes suitable for a design of an electronic device including the display device 100. For example, an exemplary shape of the active area AA may be a pentagon, a hexagon, a circle, an oval, or the like.

In the non-active area NA, various wiring lines and circuits for driving the organic light emitting diode of the active area AA may be disposed. For example, in the non-active area NA, a link line which transmits signals to the plurality of pixels and circuits of the active area AA, a gate-in-panel (GIP) line, or a driving IC, such as a gate driver 154 or a data driver 153, may be disposed, but it is not limited thereto.

The display device 100 may further include various additional elements to generate various signals or drive the pixel in the active area AA. The additional elements for driving the pixels may include an inverter circuit, a multiplexer, an electrostatic discharge (ESD) circuit, or the like. The display device 100 may further include an additional element associated with a function other than a function of driving a pixel. For example, the display device 100 may include additional elements which provide a touch sensing function, a user authentication function (for example, fingerprint recognition), a multilevel pressure sensing function, or a tactile feedback function. The above-mentioned additional elements may be located in an external circuit which is connected to the non-active area NA and/or the connecting interface.

Hereinafter, the pixel P of the present disclosure will be described in more detail with reference to FIGS. 2A to 2D together.

FIGS. 2A to 2D are plan views for one pixel of a display device according to an exemplary embodiment of the present disclosure.

Referring to FIGS. 2A to 2D, each of the plurality of pixels P includes an emission area EA including a first emission area EA1 and a second emission area EA2 disposed so as to enclose (e.g., surround) the first emission area EA1 in a plan view of the display device and a transmission area TA that is directly adjacent to the emission area EA in the plan view.

According to an example of FIG. 2A, the rectangular second emission area EA2 encloses the rectangular shaped first emission area EA1 and the transmission area TA is disposed to be directly adjacent to the emission area EA.

Even though in FIG. 2A, a structure in which both the first emission area EA1 and the second emission area EA2 are rectangular is illustrated, the shape of the emission area EA according to the exemplary embodiment of the present disclosure is not limited thereto.

For example, as illustrated in FIG. 2B, a rectangular second emission area EA2 may be disposed so as to enclose a rhombus shaped first emission area EA1 in the plan view of the display device.

According to an example of FIG. 2C, a rhombus shaped second emission area EA2 may be disposed so as to enclose a rectangular shaped first emission area EA1 in the plan view of the display device.

According to an example of FIG. 2D, a rhombus shaped second emission area EA2 may be disposed so as to enclose a rhombus shaped first emission area EA1.

Shapes of the first emission area EA1 and the second emission area EA2 are not limited to the above-described example.

The first emission area EA1 is an area in which light is emitted to implement an image. For example, the first emission area EA1 may include a 1-1-th emission area EA1-1 (e.g., a first sub emission area), a 1-2-the emission area EA1-2 (e.g., a second sub emission area), a 1-3-th emission area EA1-3 (e.g., a third sub emission area), and a 1-4-th emission area EA1-4 (e.g., a fourth sub emission area) according to a color of discharged light.

The first emission area EA1 may include a plurality of first sub pixels having an organic light emitting diode. For example, a 1-1-th sub pixel is disposed in the 1-1-th emission area EA1-1, a 1-2-th sub pixel is disposed in the 1-2-th emission area EA1-2, a 1-3-th sub pixel is disposed in the 1-3-th emission area EA1-3, and a 1-4-th sub pixel is disposed in the 1-4-th emission area EA1-4. Each of the plurality of first sub pixels may include a circuit unit which is electrically connected to the organic light emitting diode. The circuit unit may include at least one or more transistors and capacitors.

The transmission area TA may be defined as an area where external light is transmitted through the transmission area TA to allow a user to recognize an object through the display device, etc. located on a rear surface of the display device. Further, the transmission area TA may be defined as an area in which signal lines are not disposed. However, when a signal line is implemented with a transparent material to have a predetermined transparency, the signal line may be disposed also in the transmission area TA, but it is not limited thereto.

According to the exemplary embodiment of the present disclosure, in order to set an optimal viewing condition in consideration of each image quality element according to the usage environment of the display device 100, that is, an emission mode (e.g., a first mode) in which an image is implemented or a transparent mode (e.g., a second mode) in which an object, etc. located on a rear surface of the display device is recognized, a second emission area EA2 which is disposed so as to enclose the first emission area EA1 is further included. For example, the second emission area EA2 may function as an emission area or a transmission area according to the usage environment of the display device 100.

For example, the second emission area EA2 may include a plurality of second sub pixels. Each of the plurality of second sub pixels may include a circuit unit which is electrically connected to the light emitting diode. The circuit unit may include at least one or more transistors and capacitors.

For example, the second emission area EA2 may include a 2-1-th emission area EA2-1 (e.g., a first sub emission area), a 2-2-the emission area EA2-2 (e.g., a second sub emission area), a 2-3-th emission area EA2-3 (e.g., a third sub emission area), and a 2-4-th emission area EA2-4 (e.g., a fourth sub emission area) according to a color of discharged light. A 2-1-th sub pixel is disposed in the 2-1-th emission area EA2-1, a 2-2-th sub pixel is disposed in the 2-2-th emission area EA2-2, a 2-3-th sub pixel is disposed in the 2-3-th emission area EA2-3, and a 2-4-th sub pixel is disposed in the 2-4-th emission area EA2-4.

The 1-1-th emission area EA1-1 and the 2-1-th emission area EA2-1 discharge light with the same first color. The 1-2-th emission area EA1-2 and the 2-2-th emission area EA2-2 discharge light with the same second color. The 1-3-th emission area EA1-3 and the 2-3-th emission area EA2-3 discharge light with the same third color. The 1-4-th emission area EA1-4 and the 2-4-th emission area EA2-4 discharge light with the same fourth color. The first color, the second color, the third color, and the fourth color may be assigned to any one of red R, blue B, green G, and white W, respectively, and for example, the first color, the second color, the third color, and the fourth color may be red R, blue B, green G, and white W, respectively.

For example, when the 1-1-th emission area EA1-1 and the 2-1-th emission area EA2-1 emit red light, emission layers disposed in the 1-1-th emission area EA1-1 and the 2-1-th emission area EA2-1 may include a luminescent material which emits red light and the luminescent material may be formed using phosphorescent or fluorescent materials.

To be more specific, the red emission layer may include a host material including carbazole biphenyl (CBP) or mCP(1,3-bis(carbazol-9-yl) benzene). The red emission layer may be formed by a phosphorescent material including a dopant including one or more of Ir(btp)2(acac)(bis(2-benzo[b]thiophen-2-ylpyridine)(acetylacetonate)iridium(III)), Ir(piq)2(acac)(bis(1-phenylisoquinoline)(acetylacetonate)iridium(III)), Ir(piq)3(tris(1-phenylquinoline)iridium(III)), and PtOEP(octaethylporphyrin platinum). Alternatively, the red emission layer may be formed of a fluorescent material including PBD:Eu(DBM)3(Phen) or Perylene. However, the red emission layer is not limited thereto.

For example, when the 1-2-th emission area EA1-2 and the 2-2-th emission area EA2-2 emit blue light, emission layers disposed in the 1-2-th emission area EA1-2 and the 2-2-th emission area EA2-2 may include a luminescent material which emits blue light and the luminescent material may be formed using phosphorescent or fluorescent materials.

To be more specific, the blue emission layer may include a host material including CBP or mCP and may be formed of a phosphorescent material including a dopant material including FIrPic(bis(3,5,-difluoro-2-(2-pyridyl)phenyl-(2-carboxypyridyl)iridium(III)). Further, the blue emission layer may be formed of a fluorescent material including any one of DPVBi(4,4′-bis[4-di-p-tolylamin]stryl)biphenyl), DSA(1-4-di-[4-(N,N-di-phenyl)amino]styryl-benzene), PFO(polyfluorene)-based polymer, and PPV(polyphenylenevinylene)-based polymer, but is not limited thereto.

For example, when the 1-3-th emission area EA1-3 and the 2-3-th emission area EA2-3 emit green light, emission layers disposed in the 1-3-th emission area EA1-3 and the 2-3-th emission area EA2-3 may include a luminescent material which emits green light and the luminescent material may be formed using phosphorescent or fluorescent materials.

To be more specific, the green emission layer may include a host material including CBP or mCP. The green emission layer may be formed of a phosphorescent material including a dopant material such as iridium complex (Ir complex) including Ir(ppy)3(tris(2-phenylpyridine)iridium(III)) or Ir(ppy)2(acaa)(bis(2-phenylpyridine)(acetylacetonate)iridium(III). Alternatively, the green emission layer may be formed of a fluorescent material including Alq3(tris(8-hydroxyquinolino)aluminum), but is not limited thereto.

According to the exemplary embodiment of the present disclosure, the second emission area EA2 may be disposed at the outer periphery of the first emission area EA1 which discharges the same color light. Accordingly, in the emission mode, the first emission area EA1 and the second emission area EA2 which discharge the same color discharge light together to increase the emission size and in the transparent mode, only the first emission area EA1 emits light and the second emission area EA2 functions as a transparent area to improve the size of the transparent area.

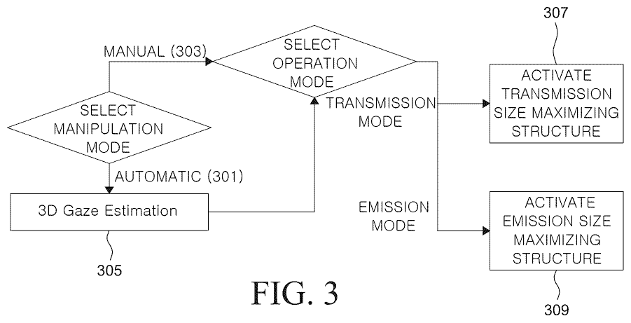

Hereinafter, an emission mode or a transparent mode of a plurality of pixels P of the present disclosure will be described in more detail with reference to FIGS. 3 to 5.

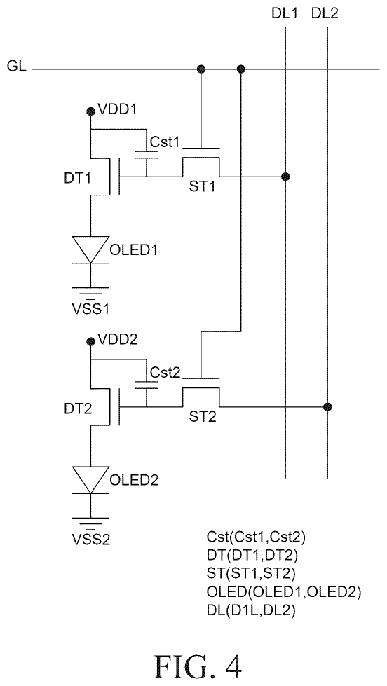

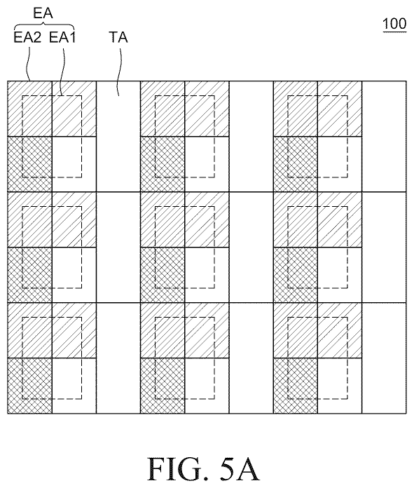

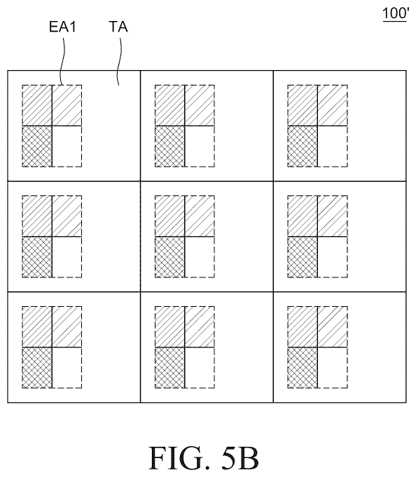

FIG. 3 is a flowchart illustrating a method for setting a plurality of pixels P to an emission mode or a transparent mode according to an exemplary embodiment of the present disclosure. FIG. 4 is an equivalent circuit diagram of each of a plurality of pixels P according to an exemplary embodiment of the present disclosure. FIG. 5A is a plan view illustrating an emission mode of the display device 100 and FIG. 5B is a plan view illustrating a transparent mode of a display device 100′ according to one embodiment.

According to the exemplary embodiment of the present disclosure, the setting 300 of the plurality of pixels P to an emission mode or a transparent mode may be automatically 301 or manually controlled 303.

According to the exemplary embodiment of the present disclosure, the emission mode or the transparent mode of the plurality of pixels P is automatically controlled 301 according to 3D gaze estimation 305 which is based a distance between user's pupils. For example, if the distance between pupils is less than or equal to a predetermined value, it is set to the emission mode and if the distance between pupils is more than or equal to a predetermined value, it is set to the transmission mode, but it is not limited thereto.

For example, when the emission mode or the transparent mode of the plurality of pixels P is manually controlled 303, any method for controlling a voltage applied to the second emission area EA2 may be used without any limitation. If the transmission mode is selected whether manually or automatically, the transmission size maximizing structure is activated 307. If the emission mode is selected whether manually or automatically, the emission size maximizing structure is activated 309.

Referring to FIGS. 3 and 4 together, the plurality of pixels P may be individually driven for each of the first emission area EA1 and the second emission area EA2.

For example, each of the first emission area EA1 and the second emission area EA2 may include a corresponding switching transistor ST, a corresponding driving transistor DT, a corresponding storage capacitor Cst, and a corresponding light emitting diode OLED.

The light emitting diode OLED may operate to emit light in accordance with a driving current formed by the driving transistor DT.

The switching transistor ST may perform a switching operation such that a data signal supplied through the data line DL is stored in the capacitor Cst as a data voltage in response to a gate signal supplied through the gate line GL.

The driving transistor DT may operate to flow a constant driving current between a high potential power line VDD and a low potential power line VSS in response to a data voltage stored in the capacitor Cst.

According to the exemplary embodiment of the present disclosure, signals supplied to a plurality of first data lines DL1 and a plurality of second data lines DL2 are controlled according to the emission mode or the transparent mode of the display device 100 to turn on or turn off the plurality of first light emitting diodes OLED1 and the plurality of second light emitting diodes OLED2. The plurality of first data lines DL1 and the plurality of second data lines DL2 are connected to the plurality of first light emitting diodes OLED1 disposed in the plurality of first emission areas EA1 and the plurality of second light emitting diodes OLED2 disposed in the plurality of second emission areas EA2, respectively.

For example, in the emission mode, all the gate line GL, the first data line DL1, and the second data line DL2 are turned on so that both the first emission area EA1 and the second emission area EA2 emit light as illustrated in FIG. 5A. Accordingly, the user may visibly recognize an image implemented in the first emission area EA1 and the second emission area EA2 and a background through the transmission area TA, simultaneously.

For example, in the transparent mode, the gate line GL and the first data line DL1 are turned on and the second data line DL2 is turned off to allow only the first emission area EA1 to emit light as illustrated in FIG. 5B and the other areas (for example, the second emission area EA2 and the transmission area TA) may function as a transparent area. A data line is “turned on” if a data voltage is transmitted on the data line and is the data line “turned off” if no data voltage is transmitted on the data line. Accordingly, the user may visibly recognize an object of the background, that is, the rear surface of the display device 100′ through the second emission area EA2 and the transmission area TA.

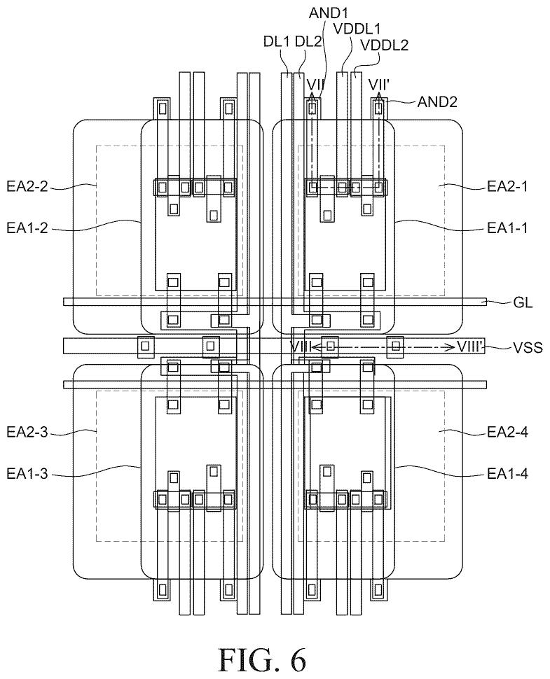

Hereinafter, an emission area EA of each of a plurality of pixels P of the present disclosure will be described in more detail with reference to FIGS. 6 to 8.

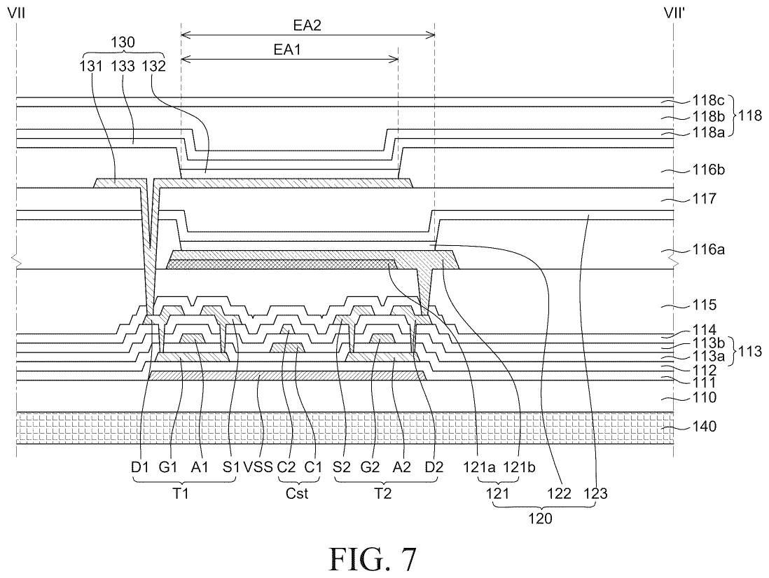

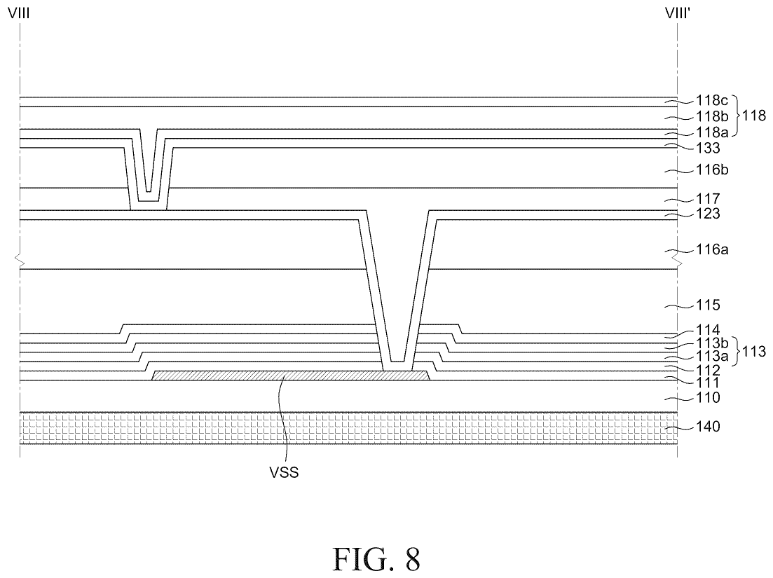

FIG. 6 is a schematic plan view illustrating an emission area of a plurality of pixels of the display device according to an exemplary embodiment of the present disclosure. FIG. 7 is a cross-sectional view taken along the line VII-VII′ of FIG. 6 according to an exemplary embodiment of the present disclosure. FIG. 8 is a cross-sectional view taken along the line VIII-VIII′ of FIG. 6 according to an exemplary embodiment of the present disclosure.

Referring to the emission area EA of FIG. 2A and FIGS. 6 to 8 together, the display device 100 according to the exemplary embodiment of the present disclosure includes a substrate 110, a plurality of first thin film transistors T1 and a plurality of second thin film transistors T2, a plurality of first light emitting diodes 130, and a plurality of second light emitting diodes 120. As shown in FIG. 7, a second light emitting diode 120 (e.g., a second light emitting element) is between a first light emitting diode 130 (e.g., a first light emitting element) and a first thin film transistor T1 (e.g., DT1) and a second thin film transistor T2 (DT2). In the example shown in FIG. 7, the first light emitting diode 130 and the second light emitting diode 120 emit a same color of light.

In the substrate 110, a first emission area EA1 and a second emission area EA2 which encloses the first emission area EA1 are defined. The plurality of first thin film transistors T1 and the plurality of second thin film transistors T2 are disposed so as to overlap the first emission area EA1. The plurality of first light emitting diodes 130 are disposed so as to overlap the first emission area EA1 and is electrically connected to the plurality of first thin film transistors T1. The plurality of second light emitting diodes 120 are disposed so as to overlap the first emission area EA1 and the second emission area EA2 and is electrically connected to the plurality of second thin film transistors T2.

The substrate 110 is a component for supporting various components included in the display device 100 and may be formed of an insulating material. For example, the substrate 110 may be a glass substrate or a plastic substrate. For example, the plastic substrate may include a material selected from polyimide, polyethersulfone, polyethylene terephthalate, polyetherimide, polymethylmethacrylate, and polycarbonate, but is not limited thereto.

A low potential power line VSS may be disposed on the substrate 110.

A multi-buffer layer 111 may be disposed on the low potential power line VSS.

On the multi-buffer layer 111, a first active layer A1 of the first thin film transistor T1 and a second active layer A2 of the second thin film transistor T2 may be disposed. For example, the first active layer A1 and the second active layer A2 may be formed of polysilicon (p-Si), amorphous silicon (a-Si), or oxide semiconductor, but are not limited thereto. For example, the first active layer A1 and the second active layer A2 may be formed on the same layer by the same process.

A gate insulating film 112 may be disposed so as to cover the first active layer Al and the second active layer A2. The gate insulating film 112 may be formed of silicon oxide (SiOx), silicon nitride (SiNx), or a double layer thereof.

A first gate electrode G1 of the first thin film transistor T1, a second gate electrode G2 of the second thin film transistor T2, and a first capacitor electrode C1 of the storage capacitor Cst may be disposed on the gate insulating film 112. For example, the first gate electrode G1 may be disposed on the gate insulating film 112 so as to overlap the first active layer A1 and the second gate electrode G2 may be disposed on the gate insulating film 112 so as to overlap the second active layer A2. The first capacitor electrode C1 may be omitted based on a driving characteristic of the display device 100 and a structure and a type of the thin film transistor, but is not limited thereto. For example, the first gate electrode G1, the second gate electrode G2, and the first capacitor electrode C1 may be formed of various conductive materials, such as magnesium (Mg), aluminum (Al), nickel (Ni), chrome (Cr), molybdenum (Mo), tungsten (W), gold (Au), or an alloy thereof or transparent conductive oxide, but are not limited thereto.

An interlayer insulating layer 113 incudes a first interlayer insulating layer 113a and a second interlayer insulating layer 113b. The first interlayer insulating layer 113a may be disposed above the first gate electrode G1, the second gate electrode G2, and the first capacitor electrode C1. The first interlayer insulating layer 113a may be configured by a single layer of silicon nitride (SiNx) or silicon oxide (SiOx) or a multi-layer thereof. In the first interlayer insulating layer 113a, a contact hole to expose a source region and a drain region of the first active area A1 of the first thin film transistor T1 and a contact hole to expose a source region and a drain region of the second active area A2 of the second thin film transistor T2 may be formed.

A second capacitor electrode C2 of the storage capacitor Cst may be disposed on the first interlayer insulating layer 113a. The second capacitor electrode C2 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof or formed of transparent conductive oxide. The second capacitor electrode C2 may be formed on the first interlayer insulating layer 113a so as to overlap the first capacitor electrode C1. Further, the second capacitor electrode C2 may be formed of the same material as the first capacitor electrode C1. The second capacitor electrode C2 may be omitted based on a driving characteristic of the display device 100 and a structure and a type of the thin film transistor.

The second interlayer insulating layer 113b may be disposed while covering the second capacitor electrode C2 disposed on the first interlayer insulating layer 113a. The second interlayer insulating layer 113b may be configured as a single layer of silicon nitride (SiNx) or silicon oxide (SiOx) or a multi-layer thereof.

In the second interlayer insulating layer 113b, a contact hole to expose a source region and a drain region of the first active area A1 of the first thin film transistor T1 and a contact hole to expose a source region and a drain region of the second active area A2 of the second thin film transistor T2 may be formed.

A first source electrode S1 and a first drain electrode D1 of the first thin film transistor T1 and a second source electrode S2 and a second drain electrode D2 of the second thin film transistor T2 are disposed on the second interlayer insulating layer 113b. The first source electrode S1 and the first drain electrode D1 are electrically connected to the first active layer A1 through the contact hole formed in the gate insulating layer 112 and the interlayer insulating layer 113. The second source electrode S2 and the second drain electrode D2 are electrically connected to the second active layer A2 through the contact hole formed in the gate insulating layer 112 and the interlayer insulating layer 113. For example, the first source electrode S1, the first drain electrode D1, the second source electrode S2, and the second drain electrode D2 may be formed of various conductive materials, such as magnesium (Mg), aluminum (Al), nickel (Ni), chrome (Cr), molybdenum (Mo), tungsten (W), gold (Au), or an alloy thereof or transparent conductive oxide, but are not limited thereto.

A passivation layer 114 may be disposed on the first source electrode S1, the first drain electrode D1, the second source electrode S2, and the second drain electrode D2. The passivation layer 114 is provided to protect the first thin film transistor T1 and the second thin film transistor T2 and may be formed of an inorganic film, for example, silicon oxide (SiOx), silicon nitride (SiNx), or a double layer thereof.

An over coating layer 115 is located on the passivation layer 114. The over coating layer 115 protects the first thin film transistor T1 and the second thin film transistor T2 and planarizes upper portions thereof.

A second anode electrode 121 which is electrically connected to the second thin film transistor T2 may be disposed on the over coating layer 115. At this time, the second anode electrode 121 may be electrically connected to the second drain electrode D2 of the second thin film transistor T2 through a contact hole provided in the over coating layer 115.

In one embodiment, the second anode electrode 121 is a multi-layered anode electrode. The second anode electrode 121 may include a structure in which a reflective layer 121a and a transparent conductive layer 121b are laminated. That is the transparent conductive layer 121b is over and above the reflective layer 121a. As shown in FIG. 7, the transparent conductive layer 121b contacts the second emission layer 122 and the second drain electrode D2 of the second transistor T2. The reflective layer 121a of the second anode electrode 121 may be disposed in an area which overlaps the first emission area EA1. For example, the reflective layer 121a may be formed of silver (Ag), aluminum (Al), gold (Au), molybdenum (Mo), tungsten (W), chrome (Cr), or an alloy thereof and the transparent conductive layer 121b may be formed of transparent conductive oxide such as ITO or IZO. Further, the second anode electrode 121 may be formed with a triple structure which further incudes a transparent conductive layer disposed below the reflective layer 121a. When the second anode electrode 121 is formed with a triple structure, am adhesive strength between the reflective layer 121a and the over coating layer 115 may be improved.

A second bank 116a may be disposed while covering the second anode electrode 121. A portion of the second bank 116a which corresponds to the second emission area EA2 may be open. A part of the second anode electrode 121 may be exposed through the open part of the second bank 116a (hereinafter, referred to as an open area). At this time, the second bank 116a may be formed of an inorganic insulating material, such as silicon nitride (SiNx) or silicon oxide (SiOx), or an organic insulating material, such as benzocyclobutene resin, acrylic resin or imide resin, but is not limited thereto.

Even though it is not illustrated, a spacer may be further located on the second bank 116a. The spacer may be configured with the same material as the second bank 116a.

The second emission layer 122 may be disposed on the second anode electrode 121 which is exposed by the second bank 116a. The second emission layer 122 may include a hole injection layer, a hole transport layer, an emission layer, an electron transport layer, and an electron injection layer. The second emission layer 122 may be configured with a single emission layer structure which emits single light or may be configured with a structure which is configured by a plurality of emission layers to emit white light.

A second cathode electrode 123 is disposed on the second emission layer 122. The second cathode electrode 123 supplies electrons to the second emission layer 122 so that the second cathode electrode may be formed of a conductive material having a low work function.

An insulating layer 117 is disposed on the second cathode electrode 123. For example, the insulating layer 117 may planarize an upper portion thereof.

A first anode electrode 131 which is electrically connected to the first thin film transistor T1 may be disposed on the insulating layer 117. As shown in FIG. 7, the first anode electrode 131 overlaps the second light emitting diode 120 such as the second anode electrode 121, the second emission layer 1223, and the second cathode 123. As a result, the first light emitting diode 130 overlaps the second light emitting diode 120 such that the first light emitting diode 130 is farther from the substrate 110 than the second light emitting diode 120.

The first anode electrode 131 may be formed of a transparent conductive layer. For example, the first anode electrode 131 may be formed of transparent conductive oxide, such as ITO or IZO. Thus, the first anode electrode 131 is a transparent anode electrode.

A first bank 116b may be disposed while covering the first anode electrode 131. A portion of the first bank 116b which corresponds to the first emission area EA1 may be open. As the second emission area EA2 is disposed so as to enclose the first emission area EA1 so that the second emission area EA2 overlaps the first emission area EA1 and the size of the first emission area EA1 may be smaller than that of the second emission area EA2. Thus, the second emission area EA2 extends past an end of the first emission area EA1.

A part of the first anode electrode 131 may be exposed through an open portion of the first bank 116b. At this time, the first bank 116b may be formed of an inorganic insulating material, such as silicon nitride (SiNx) or silicon oxide (SiOx), or an organic insulating material, such as benzocyclobutene resin, acrylic resin or imide resin, but is not limited thereto.

The first emission layer 132 may be disposed on the first anode electrode 131 which is exposed by the first bank 116b. The first emission layer 132 may include a hole injection layer, a hole transport layer, an emission layer, an electron transport layer, and an electron injection layer. The first emission layer 132 may be configured with a single emission layer structure which emits single light or may be configured with a structure which is configured by a plurality of emission layers to emit white light.

A first cathode electrode 133 is disposed on the first emission layer 132. The first cathode electrode 133 supplies electrons to the first emission layer 132 so that the second cathode electrode may be formed of a conductive material having a low work function.

An encapsulation unit 118 may be disposed above the first cathode electrode 133. The encapsulation unit 118 may have a single layer structure or a multi-layered structure. For example, the encapsulation unit 118 may include a first encapsulation layer 118a, a second encapsulation layer 118b, and a third encapsulation layer 118c.

For example, the first encapsulation layer 118a and the third encapsulation layer 118c may be configured by inorganic films and the second encapsulation layer 118b may be configured by an organic film. Between the first encapsulation layer 118a and the third encapsulation layer 118c, the second encapsulation layer 118b is the thickest and may function as a planarization layer.

The first encapsulation layer 118a is disposed on the first cathode electrode 133 and may be formed of an inorganic insulating material on which low-temperature deposition can be performed. For example, the first encapsulation layer 118a may be configured by silicon nitride (SiNx), silicon oxide (SiOx), silicon oxynitride (SiON), or aluminum oxide Al2O3. The first encapsulation layer 118a is deposited under a low temperature atmosphere so that during the deposition process, the damage of the first emission layer 133 including an organic material which is vulnerable to the high temperature atmosphere may be suppressed.

The second encapsulation layer 118b may be formed to have a smaller size than that of the first encapsulation layer 118a. In this case, the second encapsulation layer 118b may be formed to expose both ends of the first encapsulation layer 118a. The second encapsulation layer 118b may serve to enhance a planarization performance.

For example, the second encapsulation layer 118b may be formed of an organic insulating material, such as acrylic resin, epoxy resin, polyimide, polyethylene, or silicon oxy carbon (SiOC). For example, the second encapsulation layer 118b may be formed by an inkjet method, but is not limited thereto.

The third encapsulation layer 118c may be formed above the substrate 110 on which the second encapsulation layer 118b is formed so as to cover upper surfaces and side surfaces of the second encapsulation layer 118b and the first encapsulation layer 118a. At this time, the third encapsulation layer 118c may minimize or block the permeation of external moisture or oxygen into the first encapsulation layer 118a and the second encapsulation layer 118b. For example, the third encapsulation layer 118c may be configured by an inorganic insulating material, such as silicon nitride (SiNx), silicon oxide (SiOx), silicon oxynitride (SiON), or aluminum oxide Al₂O₃.

Even though it is not illustrated, an organic material layer which planarizes an upper portion of the display device may be disposed on the encapsulation unit and a cover glass may be attached onto the organic material layer.

In the meantime, a variable reflective layer 140 may be further disposed below the substrate 110. The variable reflective layer 140 may reflect light in the emission mode of the plurality of pixels P and transmit light in the transparent mode. For example, when a voltage is applied, the variable reflective layer 140 transmits the light to function as a transparent area and when a voltage is not applied, may function as a reflective layer which reflects light. The variable reflective layer 140 may be bonded to the entire lower portion of the substrate 110 or disposed to overlap the second emission area EA2 below the substrate 110, but is not limited thereto.

According to the exemplary embodiment of the present disclosure, the variable reflective layer 140 may be cholesteric liquid crystals. For example, when a voltage is applied to the cholesteric liquid crystals, all the cholesteric liquid crystals stand up to function as a transmission mode. For example, when the voltage is not applied to the cholesteric liquid crystals, the cholesteric liquid crystals may selectively reflect light according to a twisted orientation of the helix and the pitch of the repeated structure. Accordingly, colors of reflected light may be controlled in various colors by adjusting the pitch of the cholesteric liquid crystals.

When the plurality of pixels P operates in the emission mode, the first light emitting diode 130 disposed in the first emission area EA1 may emit light. For example, light emitted from the first light emitting diode 130 may be emitted to the upper portion of the substrate 110 on which the light emitting diode 130 is disposed. At this time, light generated in the first emission layer 132 of the first light emitting diode 130 may be upwardly reflected by a configuration which reflects light below the first light emitting diode 130, for example, the reflective layer 121a of the second anode electrode 121 disposed so as to correspond to the first emission area EA1, to be emitted.

In the meantime, the second light emitting diode 120 disposed in the second emission area EA2 may emit light in the emission mode and function as a transparent area in the transparent mode.

Therefore, signal lines may not be disposed in the second emission area EA2 to transmit external light. For example, the pixel circuit of the second light emitting diode 120 of the second emission area EA2 may be disposed so as to overlap the first emission area EA1, but is not limited thereto. For example, when a signal line or an electrode is disposed so as to overlap the second emission area EA2, all the signal line or the electrode disposed so as to overlap the second emission area EA2 may be configured by the transparent conductive material, but is not limited thereto.

When the plurality of pixels P operates in the emission mode, the second light emitting diode 120 disposed in the second emission area EA2 may emit light. For example, the variable reflective layer 140 disposed below the second light emitting diode 120 may function as a reflective layer in the emission mode. Light generated in the second emission layer 122 of the second light emitting diode 120 is reflected to the upper portion of the substrate 110 disposed on the second light emitting diode 120, by the variable reflective layer 140, to emit light.

When the plurality of pixels P operates in the transparent mode, the first light emitting diode 130 disposed in the first emission area EA1 emits light and the second light emitting diode 120 disposed in the second emission area EA2 and the transmission area TA may function as a transparent area. For example, the variable reflective layer 140 disposed below the second light emitting diode 120 may function as a transparent area that transmits light in the transparent mode. Accordingly, in the transparent mode, an element which interrupts transmission of external light, for example, a metal, etc. is not disposed in the second emission area EA2 and the transmission area TA so that the second emission area EA2 and the transmission area TA may function as a transparent area.

According to the exemplary embodiment of the present disclosure, in the emission mode, the second emission area EA2 emits light to improve the emission size and in the transparent mode, the second emission area EA2 functions as a transparent area to improve the transmission size. Accordingly, a ratio of the emission area and the transmission area is controlled according to the usage environment of the display device 100 to set an optimal viewing condition.

Referring to FIGS. 6 and 7, the display device may include a low potential power line VSS extending in the first direction on the substrate 110 and a plurality of high potential power lines VDD1 and VDD2 which extends in the second direction on the substrate 110 that intersects the first direction. For example, the plurality of high potential power lines VDD1 and VDD2 may be disposed so as to overlap the first emission area EA1. As the signal lines, such as the plurality of high potential power lines VDD1 and VDD2 and the data lines DL1 and DL2 are disposed so as to overlap the first emission area EA1 so that the signal line is not disposed in the second emission area EA2. Therefore, the external light may be effectively transmitted in the transparent mode.

Referring to FIGS. 6 and 8 together, the low potential power line VSS may be electrically connected to the second cathode electrode 123 of the second emission area EA2 on the substrate 110.

Further, the display device may further include a contact hole CNT which is formed in the insulating layer 117 and the first bank 116b on the second cathode electrode 123 to expose the second cathode electrode 123, and the first cathode electrode 133 may be connected to the second cathode electrode 123 through the contact hole CNT.

In other words, according to the exemplary embodiment of the present disclosure, the first cathode electrode 133 is connected to the second cathode electrode 123 and is electrically connected to the low potential power line VSS through the second cathode electrode 123. Therefore, both the first cathode electrode 133 and the second cathode electrode 123 may be applied with a power from the low potential power line VSS.

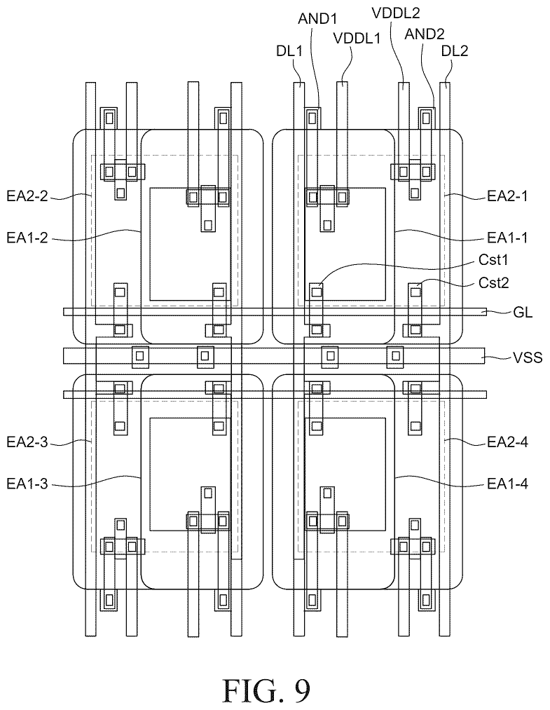

Hereinafter, a display device according to another exemplary embodiment of the present disclosure will be described in detail with reference to FIG. 9.

FIG. 9 is a schematic plan view illustrating an emission area EA of a plurality of pixels P of a display device 200 according to another exemplary embodiment of the present disclosure. The display device 200 illustrated in FIG. 9 has the substantially same configuration as the display device 100 of FIG. 6 except for a signal line connected to a second light emitting diode. Therefore, for the convenience of description, a redundant description except for a second light emitting diode and a signal line connected to the second light emitting diode, among the configuration of the display device 200, will be omitted.

Referring to FIG. 9, a high potential power line VDD2, a data line DL2, and a storage capacitor Cst2 connected to the second light emitting diode 120 may be disposed so as to overlap the second emission area EA2. For example, even though an electrode included in the second light emitting diode 120 and a signal line connected to the second light emitting diode 120 are disposed in the second emission area EA2, when the second light emitting diode 120 is formed of a transparent electrode or a signal line connected to the second emission area EA2 has a predetermined transparency, the second emission area EA2 may function as a transparent area.

For example, when an electrode included in the second light emitting diode 120 is disposed in the second emission area EA2, the second anode electrode AND2 may be formed of only a transparent conductive oxide, such as ITO or IZO, but is not limited thereto.

The exemplary embodiments of the present disclosure can also be described as follows:

According to an aspect of the present disclosure, a display device, comprising a substrate, and a plurality of pixels which is defined on the substrate and is configured to operate in an emission mode or a transparent mode, each of the plurality of pixels includes a first emission area, a second emission area which is disposed so as to enclose the first emission area, and a transmission area disposed to be adjacent to the second emission area, in the emission mode, the first emission area and the second emission area emit light, and in the transparent mode, the first emission area emits light and the second emission area and the transmission area function as a transparent area.

The first emission area includes a 1-1-th emission area which discharges a first color, a 1-2-th emission area which discharges a second color, a 1-3-th emission area which discharges a third color, and a 1-4-th emission area which discharges a fourth color, the second emission area includes a 2-1-th emission area which discharges the first color, a 2-2-th emission area which discharges the second color, a 2-3-th emission area which discharges the third color, and a 2-4-th emission area which discharges the fourth color, and the second emission area may be disposed at an outer periphery of the first emission area which emits the same color light.

Each of the plurality of pixels may further include a plurality of first thin film transistors and a plurality of second thin film transistors disposed so as to overlap the first emission area, a plurality of first light emitting diodes which is disposed so as to overlap the first emission area and is electrically connected to the plurality of first thin film transistors, and a plurality of second light emitting diodes which is disposed so as to overlap the first emission area and the second emission area and is electrically connected to the plurality of second thin film transistors.

The display device may further comprise a low potential power line extending to a first direction on the substrate, and a high potential power line which extends to a second direction on the substrate to intersect the low potential power line, the high potential power line may be disposed so as to overlap the first emission area.

The plurality of second light emitting diodes may include transparent electrodes.

The display device may further comprise a low potential power line extending to a first direction on the substrate, and a high potential power line which extends to a second direction on the substrate to intersect the low potential power line, the high potential power line may be disposed so as to overlap the second emission area.

According to another aspect of the present disclosure, a display device, comprising a substrate in which a plurality of pixels each including a first emission area, a second emission area enclosing the first emission area, and a transmission area through which light is transmitted is defined, a plurality of first thin film transistors and a plurality of second thin film transistors disposed on the substrate, an over coating layer which is disposed so as to cover the first thin film transistors and the second thin film transistors, a second anode electrode which is disposed on the over coating layer and is electrically connected to the second thin film transistor, a second bank which exposes a part of the second anode electrode on the over coating layer and defines the second emission area, a second emission layer which is disposed on the second anode electrode exposed by the second bank, a second cathode electrode on the second emission layer, an insulating layer on the second cathode electrode, a first anode electrode which is disposed on the insulating layer and is electrically connected to the first thin film transistor, a first bank which exposes a part of the first anode electrode on the insulating layer and defines the first emission area, a first emission layer which is disposed on the first anode electrode exposed by the first bank, and a first cathode electrode disposed on the first emission layer.

The plurality of pixels is configured to operate in an emission mode and a transparent mode, the first emission layer may be disposed so as to overlap a partial area of the second emission layer, in the emission mode, both the first emission layer and the second emission layer may emit light, and in the transparent mode, the first emission layer among the first emission layer and the second emission layer may emit light.

The first anode electrode may include a transparent conductive layer, and the second anode electrode may include a reflective layer which is disposed so as to overlap the first emission area and a transparent conductive layer which is disposed on the reflective layer and is disposed so as to overlap the first emission area and the second emission area.

The display device may further comprise a variable reflective layer disposed on a rear surface of the substrate, in the emission mode, the variable reflective layer may reflect light and in the transparent mode, the variable reflective layer may transmit light.

The display device may further comprise a low potential power line which is disposed on the substrate and is electrically connected to the second cathode electrode of the second emission area.

The display device may further comprise a first contact hole which is formed in the insulating layer and the first bank and exposes the second cathode electrode, the first cathode electrode may be connected to the second cathode electrode through the first contact hole.

The display device may further comprise a plurality of gate lines extending to a first direction on the substrate, and a plurality of first data lines and second data lines disposed in a second direction intersecting the first direction on the substrate, the plurality of first thin film transistors is connected to the plurality of first data lines, the plurality of second thin film transistors is connected to the plurality of second data lines, in the emission mode, the plurality of first data lines and the plurality of second data lines may be turned on, and in the transparent mode, the plurality of first data lines may be turned on and the plurality of second data lines may be turned off.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate; and
a plurality of pixels on the substrate, the plurality of pixels configured to operate in an emission mode during which the plurality of pixels emit light or a transparent mode,
wherein each of the plurality of pixels includes:
a first emission area;
a second emission area that encloses the first emission area in a plan view of the display device; and
a transmission area that is adjacent to the second emission area,
wherein the first emission area and the second emission area emit light during the emission mode, and the first emission area emits light and the second emission area does not emit light during the transparent mode such that the second emission area and the transmission area function as a transparent area during the transparent mode.

2. The display device according to claim 1, wherein the first emission area includes a first sub emission area of the first emission area that outputs a first color, a second sub emission area of the first emission area that outputs a second color, a third sub emission area of the first emission area that outputs a third color, and a fourth sub emission area of the first emission area that outputs a fourth color,
wherein the second emission area includes a first sub emission area of the second emission area that outputs the first color and is located at an outer periphery of the first sub emission area of the first emission area in the plan view, a second sub emission area of the second emission area that outputs the second color and is located at an outer periphery of the second sub emission area of the first emission area in the plan view, a third sub emission area of the second emission area that outputs the third color and is located at an outer periphery of the third sub emission area of the first emission area in the plan view, and a fourth sub emission area of the second emission area that outputs the fourth color is located at an outer periphery of the fourth sub emission area of the first emission area in the plan view.

3. The display device according to claim 1, wherein each of the plurality of pixels further includes:
a plurality of first thin film transistors and a plurality of second thin film transistors, the plurality of first thin film transistors and the plurality of second thin film transistors overlapping the first emission area;
a plurality of first light emitting diodes that overlap the first emission area, the plurality of first light emitting diodes electrically connected to the plurality of first thin film transistors; and a plurality of second light emitting diodes that overlap the first emission area and the second emission area, the plurality of second light emitting diodes electrically connected to the plurality of second thin film transistors.

4. The display device according to claim 3, further comprising:
a low potential power line extending to a first direction on the substrate; and
a high potential power line extending in a second direction on the substrate, the high potential power line intersecting the low potential power line,
wherein the high potential power line overlaps the first emission area.

5. The display device according to claim 3, wherein the plurality of second light emitting diodes includes transparent electrodes.

6. The display device according to claim 5, further comprising:
a low potential power line extending in a first direction on the substrate; and
a high potential power line that extends in a second direction on the substrate that intersects the first direction,
wherein the high potential power line overlaps the second emission area.

7. A display device, comprising:
a substrate;
a plurality of pixels on the substrate, each of the plurality of pixels including a first emission area, a second emission area enclosing the first emission area in a plan view of the display device, and a transmission area through which light is transmitted;
a plurality of first thin film transistors and a plurality of second thin film transistors on the substrate;
an over coating layer that covers the plurality of first thin film transistors and the plurality of second thin film transistors;
a second anode electrode on the over coating layer, the second anode electrode electrically connected to a second thin film transistor from the plurality of second thin film transistors;
a second bank on the second anode electrode and the over coating layer and exposes a part of the second anode electrode, the exposed part of the second anode electrode defining the second emission area;
a second emission layer on the exposed part of the second anode electrode;
a second cathode electrode on the second emission layer;
an insulating layer on the second cathode electrode;
a first anode electrode on the insulating layer and overlapping the second anode electrode, the first anode electrode electrically connected to a first thin film transistor from the plurality of first thin film transistors;
a first bank on the first anode electrode and the insulating layer and exposes a part of the first anode electrode, the exposed part of the first anode electrode defining the first emission area;
a first emission layer on the exposed part of the first anode electrode; and
a first cathode electrode on the first emission layer.

8. The display device according to claim 7, wherein the plurality of pixels are configured to operate in an emission mode and a transparent mode, and the first emission layer overlaps a partial area of the second emission layer,
wherein both the first emission layer and the second emission layer emit light during the emission mode, and the first emission layer emits light and the second emission layer does not emit light during the transparent mode.

9. The display device according to claim 8, wherein the first anode electrode includes a transparent conductive layer that overlaps the first emission area, and the second anode electrode includes a reflective layer that overlaps the first emission area and a transparent conductive layer on the reflective layer that overlaps the first emission area and the second emission area.

10. The display device according to claim 9, further comprising:
a variable reflective layer on a rear surface of the substrate,
wherein the variable reflective layer reflects light during the emission mode and the variable reflective layer transmits light during the transparent mode.

11. The display device according to claim 7, further comprising:
a low potential power line on the substrate, the low potential power line electrically connected to the second cathode electrode.

12. The display device according to claim 7, further comprising:
a first contact hole in the insulating layer and the first bank, the first contact hole exposing a portion of the second cathode electrode,
wherein the first cathode electrode is connected to the second cathode electrode through the first contact hole.

13. The display device according to claim 8, further comprising:
a plurality of gate lines extending in a first direction on the substrate; and
a plurality of first data lines and a plurality of second data lines extending in a second direction that intersects the first direction on the substrate,
wherein the plurality of first thin film transistors are connected to the plurality of first data lines and the plurality of second thin film transistors are connected to the plurality of second data lines,
wherein the plurality of first data lines and the plurality of second data lines are turned on during the emission mode, and the plurality of first data lines are turned on and the plurality of second data lines are turned off during the transparent mode.

14. A display device, comprising:
a substrate;
a first thin film transistor and a second thin film transistor on the substrate;
a first light emitting element that is connected to the first thin film transistor, the first light emitting element configured to emit light;
a second light emitting element that is connected to the second thin film transistor and is overlapped by the first light emitting element, the second light emitting element configured to emit light,
wherein the first thin film transistor drives the first light emitting element to emit light and the second thin film transistor drives the second light emitting element to emit light during a first mode of the display device, and the first thin film transistor drives the first light emitting element to emit light and the second light emitting element does not emit light during a second mode of the display device.

15. The display device of claim 14, wherein the second light emitting element is between the first light emitting element and at least one of the first thin film transistor and the second thin film transistor in a cross-section view of the display device.

16. The display device of claim 14, wherein the first light emitting element and the second light emitting element emit a same color of light.

17. The display device of claim 14, wherein the first light emitting element includes a transparent first anode electrode that is connected to the first thin film transistor, a first emission layer on the transparent first anode electrode, and a first cathode electrode on the first emission layer.

18. The display device of claim 17, wherein the second light emitting element includes a reflective layer, and a transparent conductive layer on the reflective layer, the transparent conductive layer in contact with the second emission layer and the second thin film transistor, a second emission layer on the multi-layered second anode electrode, and a second cathode electrode on the first emission layer.

19. The display device of claim 18, further comprising:
a first bank on the transparent first anode electrode and exposing a part of the transparent first anode electrode, the exposed part of the transparent first anode electrode defining a first emission area of the first light emitting element; and
a second bank on the second anode electrode and exposes a part of the second anode electrode, the exposed part of the second anode electrode defining a second emission area,
wherein the second emission area overlaps the first emission area and extends past an end of the first emission area.

20. The display device of claim 14, further comprising:
a variable reflective layer on a rear surface of the substrate,
wherein the variable reflective layer is configured to reflect light during the first mode and the variable reflective layer is configured to transmit light during the second mode.
